(19) United States
(12) Patent Application Publication
(10) Pub. No.: US 2019/0097022 A1
(43) Pub. Date: Mar. 28, 2019

(54) METHOD AND STRUCTURE TO FORM VERTICAL FIN BJT WITH GRADED SIGE BASE DOPING

(71) Applicant: International Business Machine Corporation, Armonk, NY (US)

(72) Inventors: Seyoung Kim, YORKTOWN HEIGHTS, NY (US); Choonghyun Lee, Albany, NY (US); Injo Ok, ALBANY, NY (US); Soon-Cheon Seo, ALBANY, NY (US)

(21) Appl. No.: 15/718,102

(22) Filed: Sep. 28, 2017

(51) Int. Cl. H01L 29/66; H01L 29/10; H01L 29/737; H01L 21/223; H01L 21/225

(52) U.S. Cl. CPC H01L 29/66242; H01L 29/1004; H01L 21/2252; H01L 21/2236; H01L 29/7371

(57) ABSTRACT

A device including a vertical fin bipolar junction transistor (BJT) with graded doping SiGe base with molecular layer doping (MLD), where a lower doped base is grown and a top emitter is formed and then additional late doping is provided on an Si layer on a side of the emitter and a method of manufacture thereof.

### BACKGROUND

The present invention relates generally to a vertical fin bipolar junction transistor (BJT), and more particularly, but not by way of limitation, to a vertical fin BJT transistor with granted SiGe base doping and a method of manufacturing.

Conventionally, a SiGe heterojunction bipolar transistor (HBT) has advantages over conventional ion-implanted Si-BJTs such as a reduction in base-transit time thereby resulting in higher frequency performance, an increase in collector current density and hence higher current gain, and an increase in early voltage at a particular cutoff frequency.

The base transit time can be further reduced by building into the base a drift field that aids the flow of electrons from the emitter to the collector. Some techniques use graded base doping, (i.e., a large NB near the Emitter and Base junction), which gradually decreases toward the collector base (CB) junction and others use EgB decreasing from emitter end to collector end.

However, an epitaxial emitter growing on a highly doped base is challenging and the conventional techniques are deficient. There is a need in the art to provide a gradient SiGe based doping.

### SUMMARY

In an exemplary embodiment, the present invention can provide a device including a vertical fin bipolar junction transistor (BJT) with graded doping SiGe base with MDL doping, where a lower doped base is grown and a top emitter is formed and then additional late doping is provided on an Si layer on a side of the emitter. One or more other exemplary embodiments include a computer program product and a system.

Other details and embodiments of the invention will be described below, so that the present contribution to the art can be better appreciated. Nonetheless, the invention is not limited in its application to such details, phraseology, terminology, illustrations and/or arrangements set forth in the description or shown in the drawings. Rather, the invention is capable of embodiments in addition to those described and of being practiced and carried out in various ways that should not be regarded as limiting.

As such, those skilled in the art will appreciate that the conception upon which this disclosure is based may readily be utilized as a basis for the designing of other structures, methods and systems for carrying out the several purposes of the present invention. It is important, therefore, that the claims be regarded as including such equivalent constructions insofar as they do not depart from the spirit and scope of the present invention.

### BRIEF DESCRIPTION OF THE DRAWINGS

Aspects of the invention will be better understood from the following detailed description of the exemplary embodiments of the invention with reference to the drawings, in which:

FIG. 1 exemplarily shows a high-level flow chart for a vertical fin bipolar junction transistor (BJT) manufacturing method 100 according to a first embodiment of the present invention;

FIG. 2 exemplarily shows a high-level flow chart for a vertical fin bipolar junction transistor manufacturing method 200 according to a second embodiment of the present invention;

FIGS. 3A-3K exemplarily depict a vertical fin bipolar junction transistor device and method of manufacture thereof according to the first embodiment of the present invention; and

FIGS. 4A-4H exemplarily depict a vertical fin bipolar junction transistor device and method of manufacture thereof according to the second embodiment of the present invention.

### DETAILED DESCRIPTION

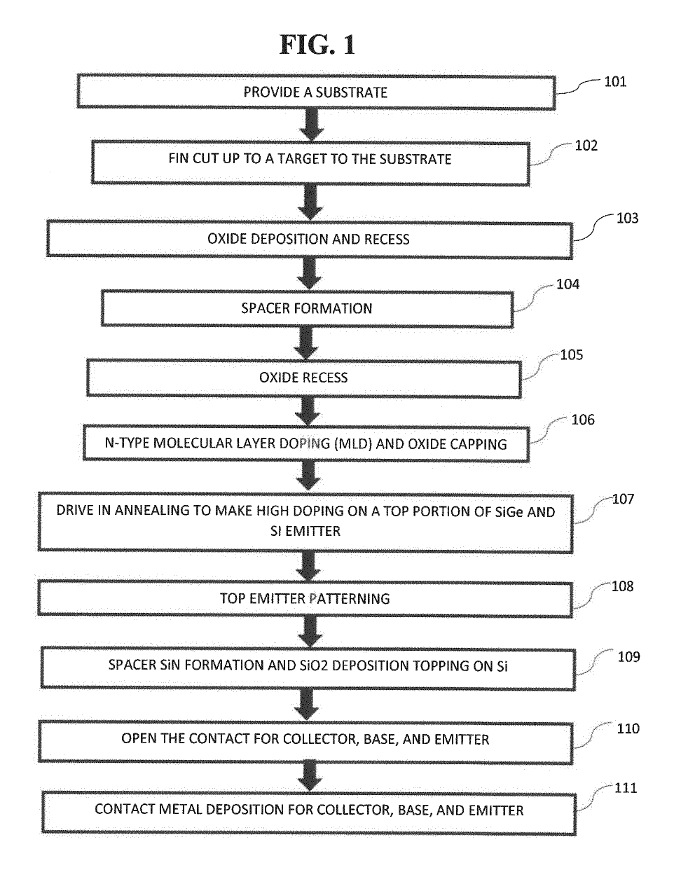

The invention will now be described with reference to FIGS. 1-4H, in which like reference numerals refer to like parts throughout. It is emphasized that, according to common practice, the various features of the drawings are not necessarily to scale. On the contrary, the dimensions of the various features can be arbitrarily expanded or reduced for clarity.

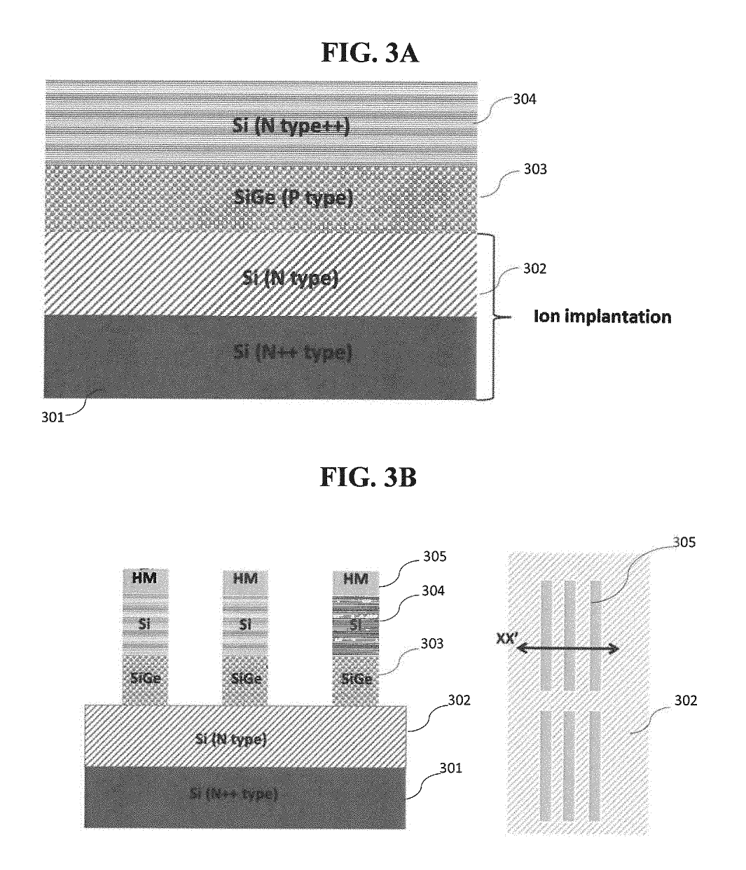

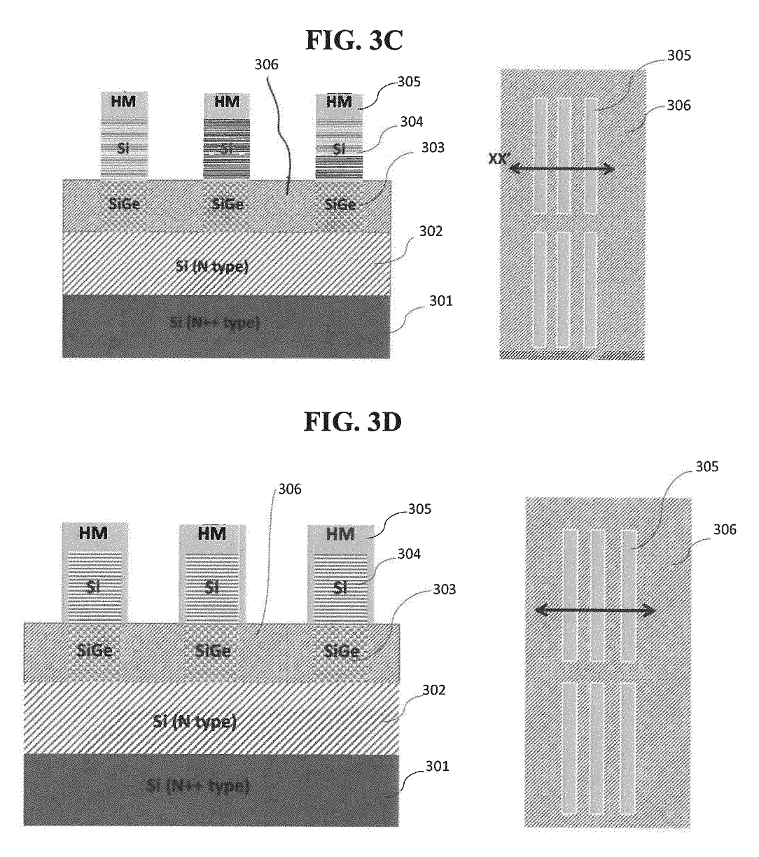

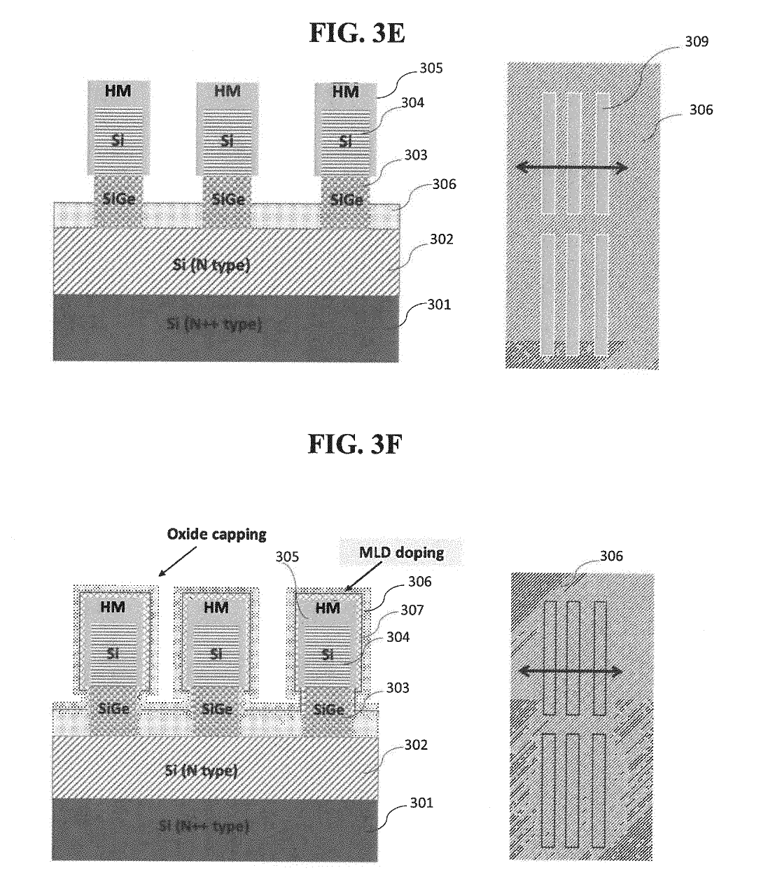

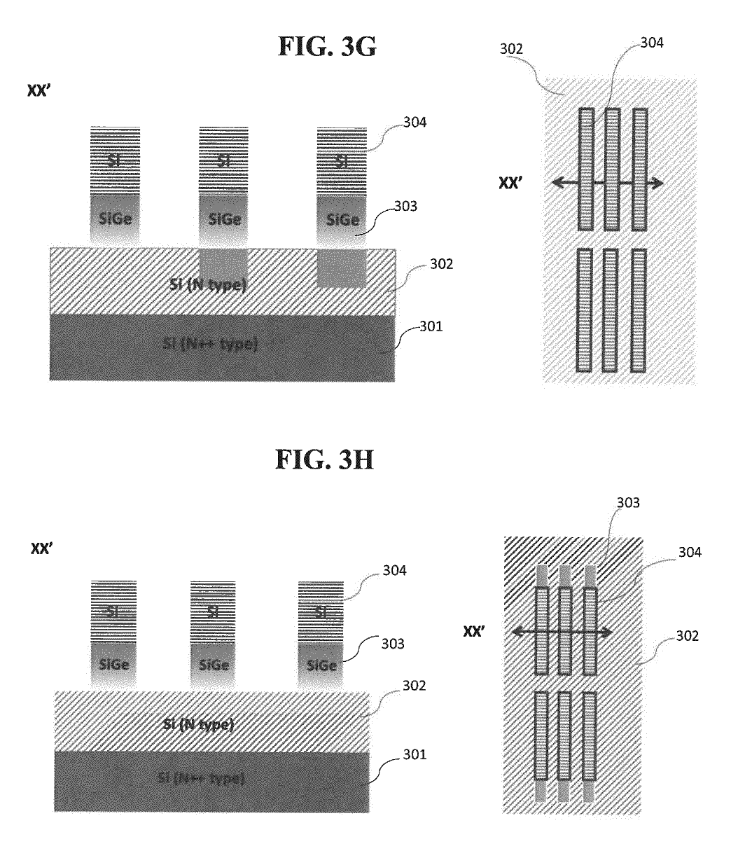

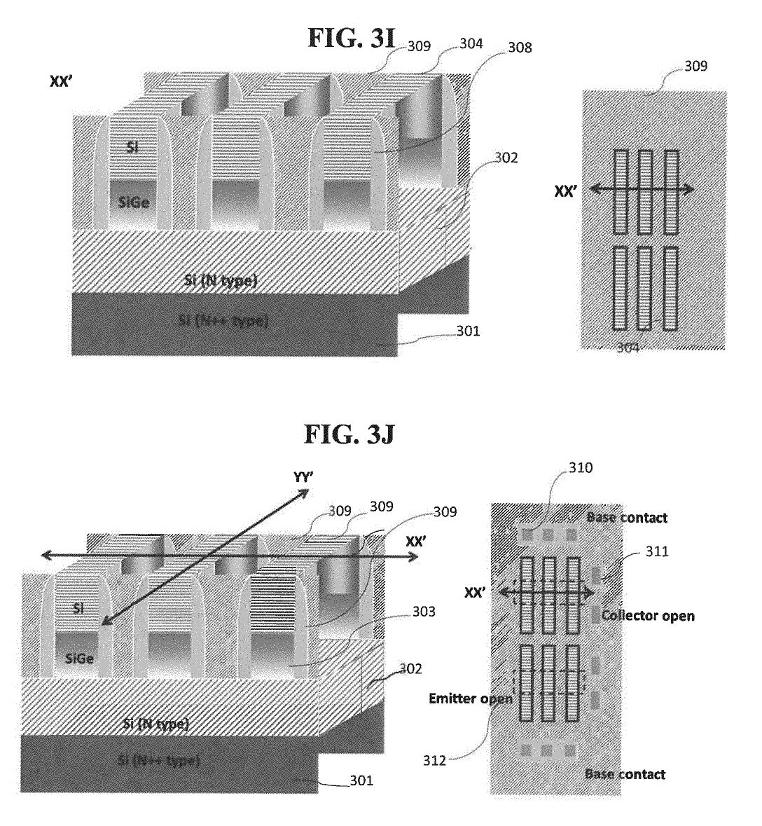

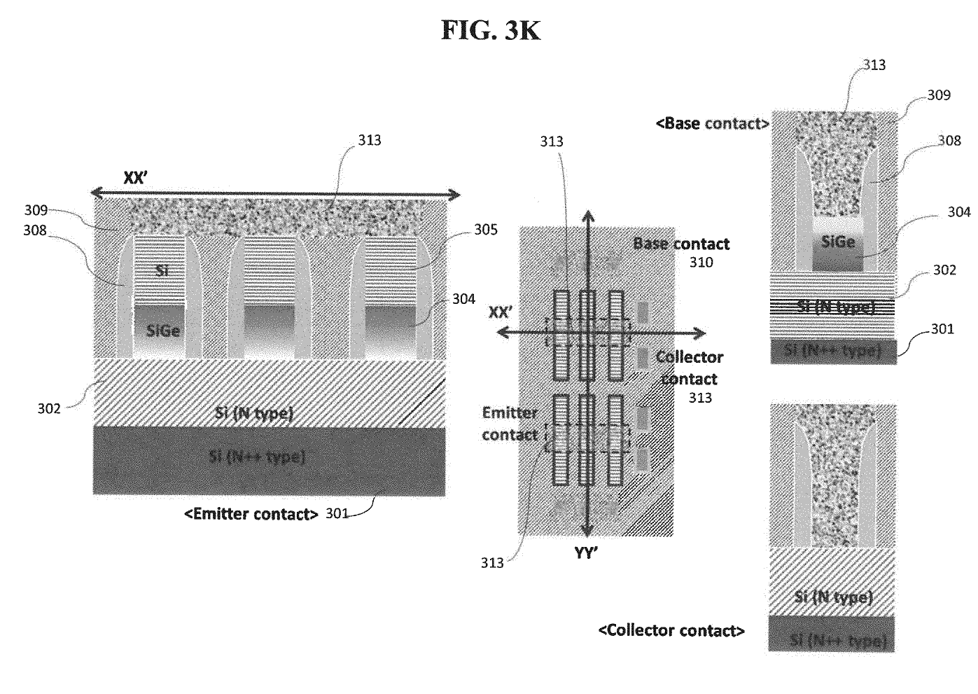

Referring to FIG. 1, FIG. 1 describes a flow of the method of manufacture 100 of the vertical fin bipolar junction transistor device corresponding to FIGS. 3A-3K according to a first embodiment.

In step 101 and as shown in FIG. 3A, a substrate is provided with ion-implantation and annealing followed by SiGe and Si epitaxial growth. The substrate includes a Si (N++ type) layer 301, Si (e.g., N type) layer 302, a SiGe (e.g., P type) layer 303, and a Si (e.g., N type++) layer 304.

In step 102 and as shown in FIG. 3B, the substrate is cut to form fin(s) to the Si layer 301. A hard mask 305 is applied to the Si layer 304. It is noted that three exemplary fins are depicted but that more fins (or less fins) may be provided and the length and width can be provided according to design constraints.

In step 103 and as shown in FIG. 3C, a field oxide deposition and recessing are performed to target position. The oxide 306 is provided up to a top surface of the SiGe layer 303.

In step 104 and as shown in FIG. 3D, a spacer is formed on sides of the emitter Si layer 304. The spacer may be SiN or the like, and formed by directional (e.g., “Y”) etching. It is noted that the SiGe layer 303 has different doping characteristics (e.g., at the bottom, high, and at the top, relatively low).

In step 105 and as shown in FIG. 3E, the oxide is selectively removed (preferably uniformly) from the SiGe layer 303 to have a recess between the hard mask 305 and the oxide 306.

In step 106 and as shown in FIG. 3F, N-type molecular layer doping (MLD) or plasma doping is performed to provide a layer 307. The layer 307 is capped with the oxide 306.

In step 107 and as shown in FIG. 3G, drive in annealing is performed to make high doping on a top portion of the SiGe layer 303 and the Si emitter 304. Thus, a graded Si layer is provided with high doping on the top portion of the side layer 303 and the Si emitter 304. The hard mask 305 and the oxide 306 are stripped.

In step 108 and as shown in FIG. 3H, a contact is created by etching (with patterning) the fin to expose the SiGe layer 303.

In step 109 and as shown in FIG. 3I, a spacer SiN 308 is formed and SiO₂ 309 deposition is performed stopping on the Si layer 304. In other words, the SiN spacer 308 is formed, oxide 309 is deposited on the fins, and chemical-mechanical planarization (CMP) is performed.

In step 110 and as shown in FIG. 3J, an opening is created for a collector 311, a base 310, and an emitter 312.

In step 111 and as shown in FIG. 3K, the contacts are created by depositing a metal 313 in the opening created for each of the collector 311, the base 310, and the emitter 312. The metal 313 is deposited on the entire surface and CMP is performed to remove metal 313 from the surface except for in the recesses. As such a structure is created and all recesses include metal.

Thereby, the method 100 may provide a gradient SiGe based doping to form a vertical HBT transistor with MLD (or plasma) doping structure and a process for vertical HBT using 5 nm technology.

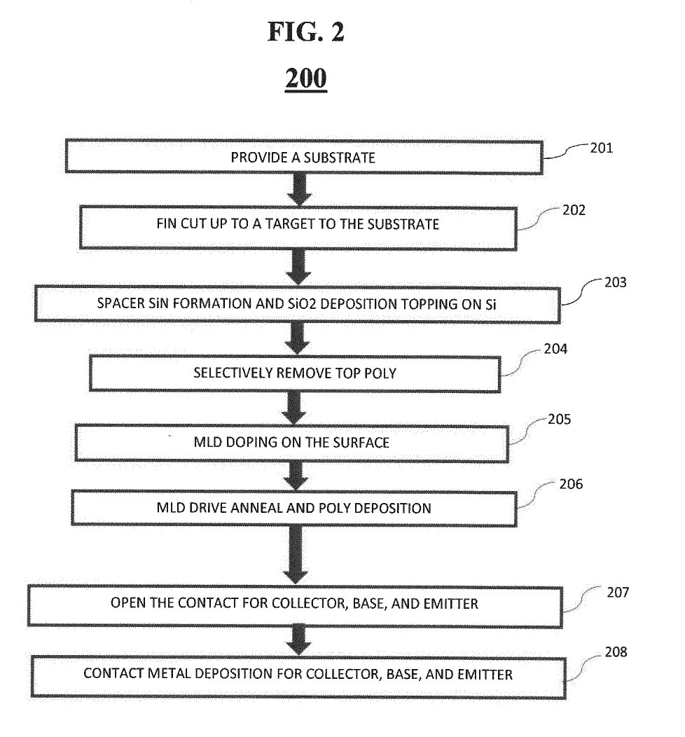

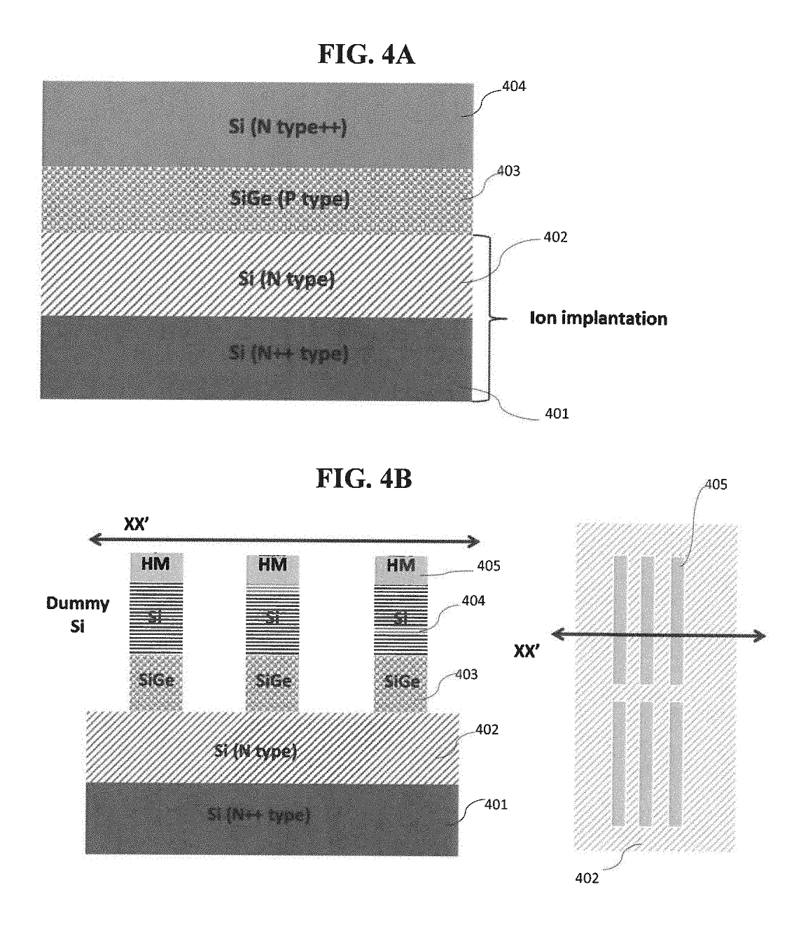

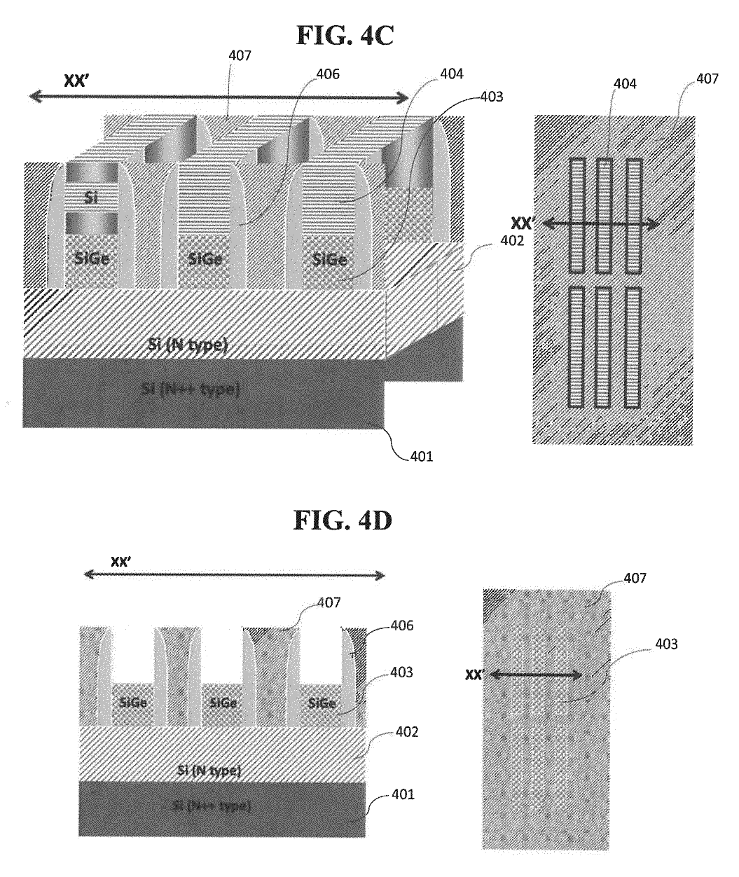

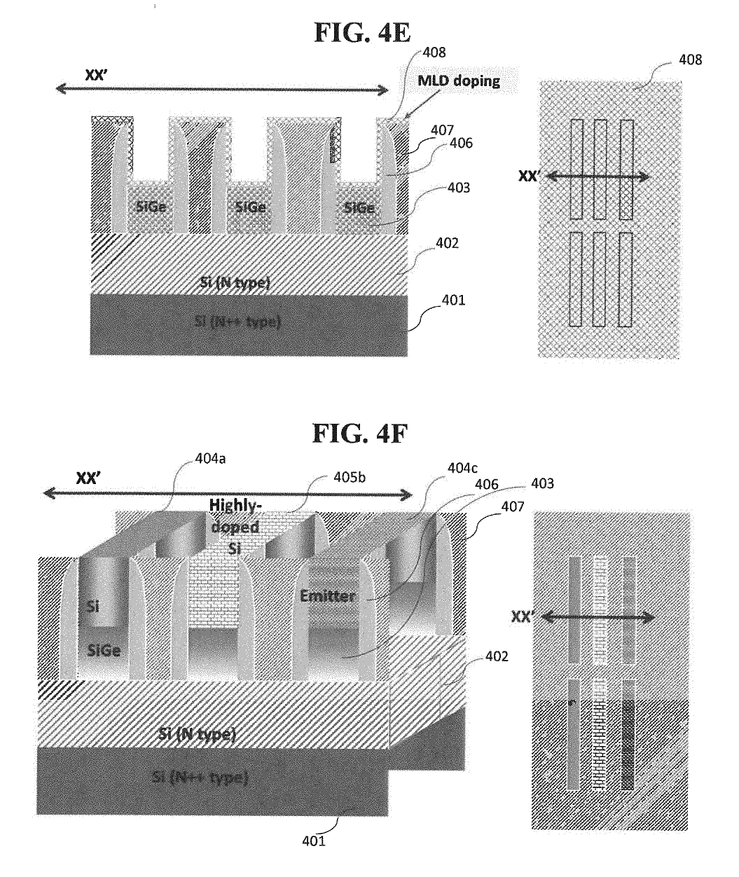

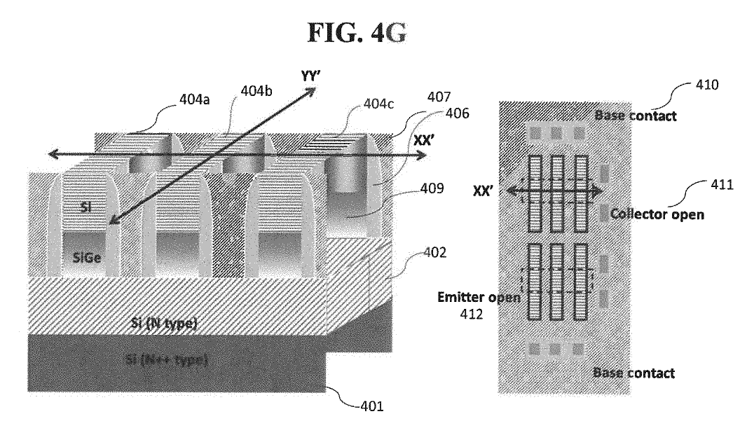

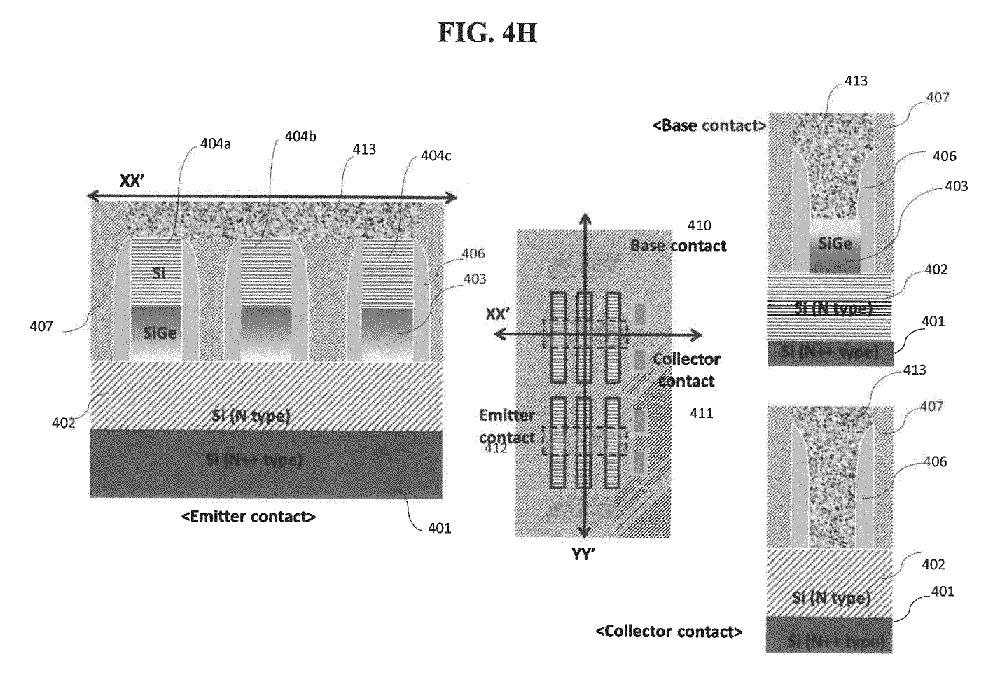

Referring to FIG. 2, FIG. 2 describes a flow of the method of manufacture 200 of the vertical fin bipolar junction transistor device corresponding to FIGS. 4A-4H according to a second embodiment.

In step 201 and as shown in FIG. 4A, a substrate is provides with ion-implantation and annealing following by SiGe and Si epitaxial growth. The substrate includes an Si (e.g., N++ type) layer 401, Si (e.g., N type) layer 402, an SiGe (e.g., P type) layer 403, and an Si (e.g., N type++) layer 404.

In step 202 and as shown in FIG. 4B, the substrate is cut to form fins targeted to the Si layer 301. A hard mask 305 is applied to the Si layer 304. It is noted that three exemplary fins are depicted but that more fins (or less fins) may be provided and the length and width can be provided according to design constraints. Further, in contrast to the first embodiment, the Si layer 404 can be a dummy layer and different materials can be provided as shown in FIG. 4F.

In step 203 and as shown in FIG. 4C, in contrast to the first embodiment, a spacer 406 is formed of SiN and an SiO₂ deposition is performed to deposit an oxide 407.

In step 204 and as shown in FIG. 4D, the top poly is selectively removed by poly pulling to remove the dummy Si layer 404.

In step 205 and as shown in FIG. 4E, MLD top doping is performed on the top surface to provide the MLD doping layer 408 over an entirety of the top surface.

In step 206 and as shown in FIG. 4F, MLD drive annealing and poly deposition (or epitaxial Si deposition) is performed. In step 206, material fills the dummy Si layer 404 void left in step 204. For example, an Si layer 404a, a highly-doped Si layer 404b, and an emitter 404c can be provided where the dummy 404 layer was previously present.

In step 207 and as shown in FIG. 4G, an opening is created for a collector 411, a base 410, and an emitter 412.

In step 208 and as shown in FIG. 3H, the contacts are created by depositing a metal 413 in the opening created for each of the collector 411, the base 410, and the emitter 412. The metal 413 is deposited on the entire surface and CMP is performed to remove metal 413 from the surface except for in the recesses.

Thereby, the method 200 may provide a gradient SiGe based doping to form a vertical HBT transistor with MLD (or plasma) doping structure and a process for vertical HBT using 5 nm technology.

In the embodiments described herein, growing lower doped base and forming top emitter and then additional late doping can be performed to provide highly doped Base on emitter side (gradient SiGe Base doping).

Moreover, the methods 100 and 200 can provide a structure of Fin BJT with graded doping SiGe base which include additional MDL (plasma) doping provide gradient SiGe based doping by growing lower doped base and forming top emitter and then additional late doping can provide highly doped base on emitter side (gradient SiGe Base doping).

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Further, Applicant's intent is to encompass the equivalents of all claim elements, and no amendment to any claim of the present application should be construed as a disclaimer of any interest in or right to an equivalent of any element or feature of the amended claim.

1. A device comprising:
a vertical fin bipolar junction transistor (BJT) with a graded doping SiGe base with molecular layer doping (MLD),
wherein:
a lower-doped base is grown as the graded doping SiGe base having a low doping characteristic at an upper portion of the lower-doped base and a high doping characteristic at a lower portion of the lower-doped base;
a top emitter including Si is formed on the top portion of the lower-doped base; and
the low doping characteristic at the upper portion of the lower-doped base is changed to a high doping characteristic via the MLD such that the too emitter and the upper portion and the lower portion of the lower-doped base include the high doping characteristic.

2. The device of claim 1, wherein the fin BJT includes:
a base contact formed of a metal deposited between an oxide and a spacer on the SiGe base; and
a collector contact formed of the metal deposited between the oxide and the spacer on an Si (N type) layer and an Si (N++ type) layer of a substrate.

3. The device of claim 1,
wherein a pitch of the vertical fin bipolar junction transistor (BJT) is approximately 5 nm.

4. A method of manufacturing a vertical fin bipolar junction transistor (BJT), the method comprising:
selectively removing an oxide from a recess between fins at a top portion of an SiGe layer;
performing doping around an Si layer and the recess around the SiGe layer; and
drive in annealing to make the SiGe layer highly doped at the top portion of the SiGe layer and the Si layer.

5. The method of claim 4, further comprising:
prior to the selectively removing, depositing the oxide in the recess of the fins of the fin BJT up to a top surface of the SiGe layer; and
forming a spacer surrounding the Si layer which is disposed on the top surface of the SiGe layer,
wherein the top portion of the SiGe layer is between a top surface of the removed oxide below the top surface of the SiGE layer and a bottom of the spacer.

6. The method of claim 4, wherein the doping includes:
plasma doping; and
N-type molecular layer doping (MLD).

7. The method of claim 4, wherein the removing removes the oxide uniformly from the top portion of the SiGe layer.

8. The method of claim 4, further comprising:
patterning to create a contact by etching the Si layer at an edge of the fins to expose the SiGe layer.

9. The method of claim 8, further comprising:
forming a second spacer surrounding the Si layer and the SiGe layer; and
depositing an oxide in the recess between the second spacer.

10. The method of claim 9, further comprising performing etching to open a collector contact, a base contact, and an emitter contact.

11. The method of claim 10, wherein the base contact corresponds to ends of the fins where the Si layer is exposed from the SiGe layer during the patterning.

12. The method of claim 10, wherein the collector contact is opened by etching to a bottom of a substrate of the fin BJT.

13. The method of claim 10, further comprising depositing a contact metal for the collector contact, the base contact, and the emitter contact.

14. The method of claim 13, wherein the contact metal is deposited over the entire fin BJT structure and chemical-mechanical planarization (CMP) is performed to remove excess of the contact metal.

15. A method of manufacturing a vertical fin bipolar junction transistor (BJT), the method comprising:
forming a spacer on a substrate between fins of the fin BJT surrounding an SiGe layer and a dummy Si layer;
depositing an oxide between the spacer of adjacent fins;
selectively removing the dummy Si layer to expose the SiGe layer between the spacer;
performing doping between the spacer and to the SiGe layer;
drive-in annealing to make the SiGe layer highly-doped; and
depositing different types of Si layers in a gap between the spacer above the highly doped SiGe layer.

16. The method of claim 15, further comprising performing etching to open a collector contact, a base contact, and an emitter contact.

17. The method of claim 16, wherein the base contact corresponds to the ends of the fins where the Si layer is exposed from the SiGe layer during the patterning.

18. The method of claim 16, wherein the collector contact is opened by etching to a bottom of a substrate of the fin BJT.

19. The method of claim 16, further comprising depositing a contact metal for the collector contact, the base contact, and the emitter contact.

20. The method of claim 19, wherein the contact metal is deposited over the entire fin BJT structure and chemical-mechanical planarization (CMP) is performed to remove excess of the contact metal.
